(19) United States
(12) Patent Application Publication
(10) Pub. No.: US 2010/0304308 A1
(43) Pub. Date: Dec. 2, 2010

(54) PROCESS FOR THICK FILM CIRCUIT PATTERNING

(75) Inventors: ATSUHIKO SATO, Utsunomoiya (JP); Isao Hayashi, Tokyo (JP); Mamoru Murakami, Yokohama (JP)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(73) Assignee: E. I. DU PONT DE NEMOURS AND COMPANY, Wilmington, DE (US)

(21) Appl. No.: 12/475,655

(22) Filed: Jun. 1, 2009

(51) Int. Cl. G03F 7/20

(52) U.S. Cl. 430/322

(57) ABSTRACT

The invention relates to forming an electrically functional pattern on a substrate and to a process for using a photosensitive element in combination with a sheet having a thick film composition applied to a support. The process for forming a pattern having electrically functional properties on a substrate comprises the steps of: (a) providing a photosensitive layer having a tacky surface disposed on a substrate; (b) image-wise exposing the photosensitive layer to form an imaged layer having tacky and non-tacky areas; (c) applying a sheet comprising at least one layer of a thick film composition disposed on a support to the imaged layer wherein the imaged layer is in contact with the thick film composition of the sheet; (d) heating the transfer sheet and the photohardenable layer to increase the adhesive strength between the thick film composition and tacky areas of the imaged layer; (e) removing the support wherein the thick film composition remains on the support in the non-tacky areas of the imaged layer and the thick film composition substantially adheres to the tacky areas of the imaged layer forming a patterned article; and (f) heating the thick film composition of the patterned article.

### FIELD OF THE INVENTION

The invention relates to forming an electrically functional pattern on a substrate. More specifically, the invention relates to a process for using a photosensitive element in combination with a sheet having a thick film composition applied to a support.

### TECHNICAL BACKGROUND OF INVENTION

U.S. Pat. No. 7,052,824 discloses a process for thick film circuit patterning as follows. A photohardenable tacky layer is applied onto a substrate, the photohardenable tacky layer is exposed to a reverse pattern of a desired pattern, and a thick film composition is caused to adhere to non-exposed positions that retain a tacky surface, to form thereby a patterned article in which no thick film composition is adhered at exposed and hardened positions.

High pressure laminators have been conventionally used for transferring a thick film composition onto a tacky surface. However, there are no laminators capable of high-pressure lamination over large transfer surface areas. Moreover, the substrate may break during lamination at high pressure when using a substrate of weak stiffness, such as glass.

There is a need to provide an improved method for forming a thick film pattern that allows for easily transferring a thick film composition onto a tacky surface, without using a high pressure laminator.

### SUMMARY OF THE INVENTION

The present invention is directed to a process for forming a pattern having electrically functional properties on a substrate comprising the steps of: (a) providing a photosensitive layer having a tacky surface disposed on a substrate; (b) image-wise exposing the photosensitive layer to form an imaged layer having tacky and non-tacky areas; (c) applying a sheet comprising at least one layer of a thick film composition disposed on a support to the imaged layer wherein the imaged layer is in contact with the thick film composition of the sheet; (d) heating the transfer sheet and the photohardenable layer to increase the adhesive strength between the thick film composition and tacky areas of the imaged layer; (e) removing the support wherein the thick film composition remains on the support in the non-tacky areas of the imaged layer and the thick film composition substantially adheres to the tacky areas of the imaged layer forming a patterned article; and (f) heating the thick film composition of the patterned article. The heating temperature in step (d) preferably ranges from 30° C. to 100° C. In step (d), the transfer sheet and the photohardenable layer may preferably be pressure-bonded using a surface-heated roll. When a surface-heated roll is used, the transfer speed of the transfer sheet and the photohardenable layer in step (d) more preferably ranges from 0.5 m/min to 5.0 m/min.

The above process also may be practiced without exposure of a tacky surface resulting in full coverage of the tacky surface by the thick film composition.

The present invention allows for easily forming a thick film pattern without using a high pressure laminator, when the transfer surface area is large or when the thick film is transferred onto a substrate having weak stiffness.

### BRIEF DESCRIPTION OF THE DRAWINGS

FIG. 1 is an illustrative diagram depicting an embodiment of the process of the present invention.

FIG. 2 is an illustrative diagram depicting an embodiment of the examples using a roll press laminator.

### DETAILED DESCRIPTION OF THE INVENTION

In the present invention, the adhesive strength between the thick film composition of a transfer sheet and a photohardenable tacky layer is increased by way of a process in which the transfer sheet and the photohardenable tacky layer are heated at a predetermined temperature.

Generally, a thick film composition comprises a functional phase that imparts appropriate electrically functional properties, such as, conductive, resistive and dielectric properties. The functional phase comprises electrically functional powders dispersed in an organic medium that acts as a carrier for the functional phase. The functional phase determines the electrical properties and influences mechanical properties of a dried thick film. There are two main types of thick film compositions that may be utilized in this invention. Both are conventional products sold in the electronics industry. The first, are thick film compositions wherein the organics of the compositions during processing are burned or fired out. These are referred to as “firable thick film compositions”. They typically comprise conductive, resistive or dielectric powders and inorganic binder dispersed in organic medium. Prior to firing, a processing requirement may include an optional heat treatment such as: drying, curing, reflow, soldering and other processes known to those skilled in the art of thick film technology. The second are thick film compositions that typically comprise conductive, resistive or dielectric powders and are dispersed in organic medium wherein the compositions during processing are cured and the organics that remain are referred to as “polymer thick film compositions”. Fireable thick film compositions and polymer thick film compositions are generally referred to as “thick film compositions”. “Organics” comprise polymer or resin components of a thick film composition.

In conductor applications the functional phase is comprised of electrically functional conductor powder(s). The electrically functional powders in a given thick film composition may comprise a single type of powder, mixtures of powders, alloys or compounds of several elements. Examples of such powders include: gold, silver, copper, nickel, aluminum, platinum, palladium, molybdenum, tungsten, tantalum, tin, indium, lanthanum, gadolinium, boron, ruthenium, cobalt, titanium, yttrium, europium, gallium, sulfur, zinc, silicon, magnesium, barium, cerium, strontium, lead, antimony, conductive carbon, and combinations thereof and others common in the art of thick film compositions.

In the present invention, the thick film compositions could be not only the conductive compositions described above but also resistor compositions or dielectric compositions. The conductive compositions, the resistor compositions and the dielectric compositions and their transfer sheets are disclosed in U.S. Pat. No. 7,052,824, incorporated herein by reference.

### Process Description and Materials

The process of the present invention comprises a photosensitive polymer layer that is applied onto a substrate surface. In a patterning process, a photohardenable tacky layer is formed on the substrate surface, and then the photohardenable tacky layer is exposed via a photomask having a desired pattern. A pattern is imaged onto a tacky photosensitive polymer layer using actinic radiation; the exposed areas of the polymer layer undergo a chemical change that renders the areas non-tacky. The surface of the photohardenable tacky layer is heated next at a suitable temperature. A subsequent application of a thick film transfer sheet, preferably by lamination, will cause a thick film composition which has electrically functional properties to adhere only at the tacky patterned areas. Upon peeling off the transfer sheet, a thick film print of the pattern will be produced on top of the tacky areas of the imaged photosensitive layer. Typical processing conditions as prescribed by the thick film composition used on the transfer sheet will then be followed.

The new thick film patterning approach comprises the following materials and process steps:

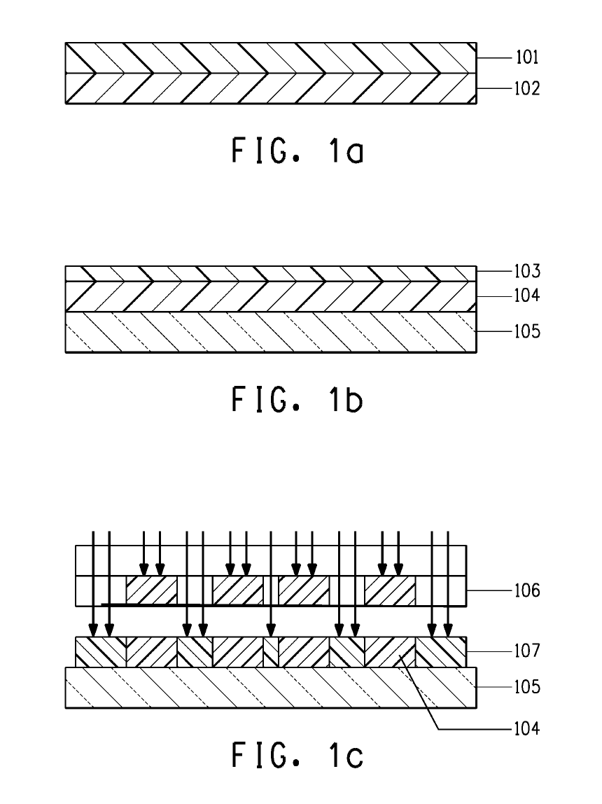

A sheet, referred to as a transfer sheet for illustration purposes, is depicted by FIG. 1(a). It comprises at least one layer of a dried-strippable thick film composition (101), preferably a fireable thick film composition, with powders, inorganic binders and organic mediums as found in the thick film compositions as described hereinabove, deposited on a support (102).

The thick film composition is deposited, for example, by casting, printing or spraying on a strippable support and then dried. During drying the volatile organic solvents are evaporated. The support is a delivery vehicle for applying the dried thick film composition to an imaged photosensitive layer. The dried-strippable thick film composition layer has sufficient adhesion to the support to remain affixed to the support throughout the required process steps, but at the same time, the adhesive strength of the dried-strippable layer is carefully balanced with the adhesive strength of the strippable support so the thick film composition could be deposited on an imaged photosensitive layer to carryout the steps in the process of the invention.

The strippable support may comprise almost any material that has reasonable flexibility and integrity. A single layer or multiple layers of a thick film composition may be applied to the support. The support is generally smooth and flat and dimensionally stable. A polyester or polyolefin film e.g. polyethylene polypropylene are examples of suitable supports. Examples of suitable materials that can be used as a support include MYLAR. polyester (polyethylene terepthalate) film available from E.I. du Pont de Nemours and Company and TRESPAPHAN® film available from Hoechst, Winston-Salem, N.C. The support typically has a thickness of 10 to 250 microns. The support may be in sheet form, which may be proportional to the size of the pattern that needs to be created or the support may be in a continuous roll. The roll will allow for continuous mass production. Optionally, a flexible cover sheet may be present on the outmost layer of the dried thick film composition layer. The cover sheet protects the underlaying areas and is easily removable.

The process employs a photosensitive layer having a tacky surface. The photosensitive layer could comprise an optional strippable support or base layer, a photosensitive tacky layer and a strippable cover sheet, wherein the strippable support has greater adhesion to the photosensitive tacky layer than the strippable cover sheet. Actinic radiation impinges on the photosensitive layer containing at least one photoactive component to induce a physical or chemical change in that material. In the photosensitive compositions which are useful in the present invention, exposure to actinic radiation causes a change in the tackiness of the layer. This element would be a positive working element as known in the art of photolithography. Examples would be CROMALIN®. photosensitive products sold by E.I. du Pont de Nemours and Company, Wilmington, Del. Descriptions of positive working photosensitive elements are disclosed in U.S. Pat. Nos. 3,649,268; 4,734,356 (positive working photosensitive elements including a support layer, a photosensitive layer having a binder component, an ethylenically unsaturated monomer component and a photopolymerizable initiator, and optionally a cover sheet); U.S. Pat. No. 4,849,322 (a multilayer element comprising a cover sheet, photo-adherent layer and tonable contiguous layer); U.S. Pat. Nos. 4,892,802; 4,948,704; 4,604,340 and 4,698,293.

In the case where the photosensitive compositions become less tacky to non-tacky (hereinafter referred to as “non-tacky”) when image-wise exposed to actinic radiation, the composition is referred to as “photohardenable”. Photohardenable systems are well known and preferred in the present invention and generally include a photoinitiator or photoinitiator system (hereinafter referred to collectively as “photoinitiator system”), and at least one compound which reacts with the species generated by exposure of the photoinitiator to actinic radiation, causing a decrease in tackiness, an ethylenically unsaturated compound, and a binder. In this context, the photoinitiator system, when exposed to actinic radiation, acts as a source of free radicals needed to initiate polymerization and/or cross-linking of the ethylenically unsaturated compound. Although not limited to photohardenable systems, the photosensitive layer of the element of the invention will be further described in terms of such systems.

The photoinitiator system has one or more compounds that directly furnish free radicals when activated by actinic radiation. The system also may contain a sensitizer that is activated by the actinic radiation, causing the compound to furnish the free radicals. Useful photoinitiator systems can also contain a sensitizer that extends spectral response into the near ultraviolet, visible, and near infrared spectral regions. Photo-initiator systems are well known and discussions of such systems can be found in, for example, “Photo-reactive Polymers: The Science and Technology of Resists” by A. Reiser, John Wiley & Sons, New York, 1989, and “Radiation Curing: Science and Technology” edited by S. P. Pappas, Plenum Press, New York, 1992. The photohardenable tacky composition comprises a photoinitiator, a polymerizable monomer, an organic binder, a solvent and an additive. Details about these components are set forth in U.S. Pat. No. 7,052,824.

FIG. 1(b) illustrates an assembly wherein a removable base layer was removed from a photohardenable layer (104) that has a tacky surface and an optional cover layer (103) such as MYLAR® film, followed by laminating the photohardenable layer onto a substrate (105). Substrates that may be used in the assembly could be rigid or flexible, and permanent or temporary, and are known by those skilled in the art of circuit assembly. Some examples of substrates include: glass panels (for example, a soda lime glass), glass-ceramic, low-temperature co-fired ceramics, alumina, aluminum oxide, and coated substrates, such as porcelainized steel, glazed ceramic substrates, and insulated metal substrates which are insulated with ceramic, glass or polymer. The substrates could be in their fired or green state. The photohardenable layer is sandwiched between the substrate and the cover layer. The cover layer is transparent for actinic radiation penetration and protects the tacky surface of the photohardenable layer.

As illustrated by FIG. 1(c), image-wise exposing the photohardenable layer with actinic radiation through a patterned photomask (106) causes detackification of the exposed areas of the photohardenable layer (107) forming a pattern, for example a circuit pattern which would have electrically functional properties. The circuit pattern is a positive image wherein it would be the same as that found on the photomask. After exposure, if present, the cover sheet on the photohardenable layer is removed. FIG. 1(d) illustrates the transfer sheet (thick film material side facing the imaged photohardenable layer) laminated onto the photohardenable layer (104) and (107). The thick film composition (101) will substantially adhere to the unexposed tacky areas of the photohardenable layer.

In the present invention, the transfer sheet and the photohardenable layer are then heated to increase the adhesive strength between the thick film composition and the tacky areas of the imaged photohardenable layer. Preferably, the transfer sheet and the photohardenable layer are heated and pressure-bonded using a surface-heated roll. For instance, a laminate comprising the transfer sheet, the imaged photohardenable layer and the substrate can be run between two rollers in a roll press laminator. The thick film composition of the transfer sheet can herein be transferred to a predetermined pattern, without breaks, by heating at least one of the rollers.

The heating temperature is preferably not lower than 30° C. At a temperature lower than 30° C., the thick film composition of the transfer sheet may fail to adhere sufficiently onto the photohardenable tacky layer (104). When forming a fine pattern having a smallest line width of 80 μm or less, the heating temperature is more preferably not lower than 40° C. Preferably, the heating temperature does not exceed 100° C., since a heating temperature above 100° C. may result in adhesion of thick film composition outside the tacky areas. More preferably, the heating temperature does not exceed 70° C. when forming a fine pattern.

When the transfer sheet and the photohardenable layer are thermally pressure-bonded using rollers, the transfer speed with which the transfer sheet and the photohardenable layer pass between the rollers is preferably not lower than 0.5 m/min. An excessively slow speed results in low productivity. Preferably, the transfer speed does not exceed 5.0 m/min, and more preferably, does not exceed 3.0 m/min. An excessively fast run between the rollers may preclude the thick film composition from adhering sufficiently to the tacky layer. However, the heating temperature of the rollers and the transfer speed of the laminate influence each other, and hence the transfer speed is slowed down in case of a low heating temperature, and is sped up in case of a high heating temperature.

The transfer sheet is stripped once the thick film composition of the transfer sheet has become adhered to the photohardenable tacky layer, as described above. After peeling the used transfer sheet, which has a reverse circuit pattern formed thereon, off of the photohardenable layer, a thick film circuit pattern is produced forming an article as illustrated in FIG. 1(e). The presently available materials that make up the photohardenable layer will be fired or burned-out at about 400° C. Thus, if complete burnout and removal of the photohardenable layer is desired, then the recommended firing temperature is above 400° C.

In order to achieve adhesion of the thick film composition when firing in the 400 to 1000° C. temperature range, it was mentioned that a glass frit/inorganic binder system in the thick film composition is important. In some special cases, this requirement might not be necessary. When an inorganic binderless thick film composition is applied to a substrate that contains dielectric or glassy components with a softening point close to the firing/sintering temperature of the binderless thick film composition, then the substrate surface itself can replace the role of the glass/inorganic powders in the traditional thick film composition. Additionally, if the conductive, resistive or dielectric powder itself is coated with some kind of glass or ceramic (or mixture thereof), this coating can act as the inorganic binder system of the thick film composition. The glass/ceramic coating can be applied in a number of ways including spraying, solution dipping, aerosol reduction, precipitation, vapor deposition, tumbling and so on. The coated particles can be heat treated for a uniform and robust coating.

In another embodiment, it is possible to skip the exposure or imaging step of the photohardable layer disposed on a substrate as described above. In absence of an imaging step, once the cover sheet of the photohardenable layer is removed the entire surface of the photohardenable layer will remain tacky. Upon lamination of a transfer sheet to the tacky photohardenable layer and removal of the sheet, the thick film composition of the transfer sheet will substantially remain on the photohardenable layer. Therefore, the pattern created will be full coverage of the unexposed area. This is especially useful in dielectric thick film composition applications.

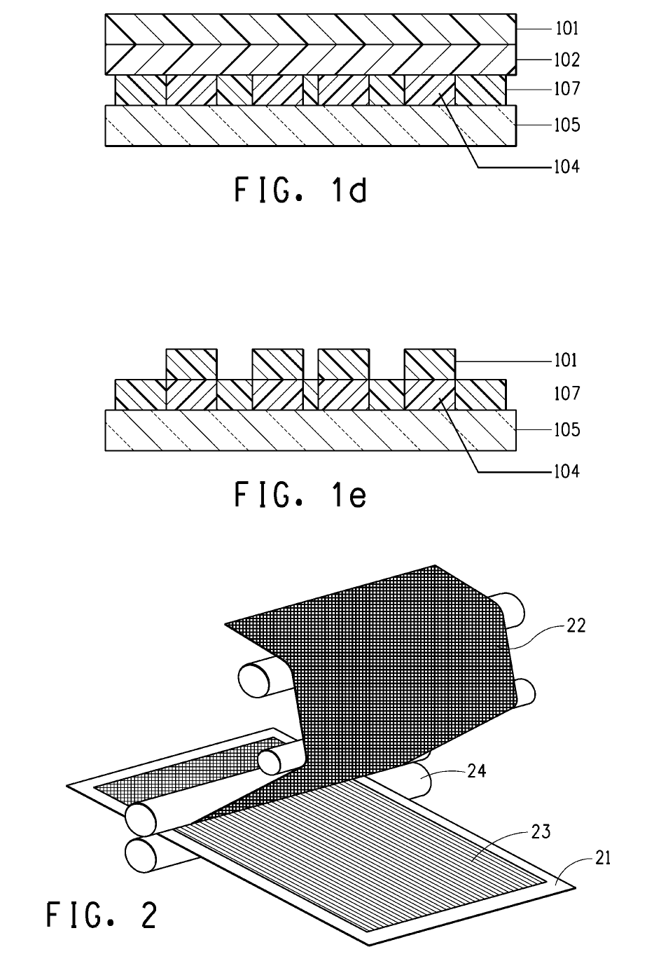

The present invention can also be used in the polymer thick film composition patterning method using negative image process set forth in column 11 and FIG. 2 of U.S. Pat. No. 7,052,824. In this case, heating of the transfer sheet and the photohardenable tacky layer is carried out after lamination of the imaged photohardenable layer onto the polymer thick film composition transfer sheet (see FIG. 2(c)).

The new processes described herein offer many advantages, including capabilities for large area substrates, precision and high density patterning, uniform metallization thickness across the whole substrate surface, automated mass production capabilities, applicable to various shape, type, flexible and rigid substrates (for example: polyester, polyolefin, polycarbonate, PVC, MYLAR®), TRESPAPHAN®, polystyrene, printed wiring board, laminates, BT, polyimide, paper, metal or other sheets, glass, ceramics-oxide and nonoxide, green-unfired ceramics and glass ceramics), sequential or single firing/cofiring/curing multilayer patterning and so on.

### EXAMPLES

### (A) Formation of Transfer Sheet

The process for casting a thick film silver containing composition on a TRESPAPHAN® support is described. The transfer sheet produced is used in Examples herein below unless otherwise specified in the example. All percentages are in weight percent unless otherwise stated. In a stoneware ceramic jar, the following ingredients were added: Alumina Beads, filling the jar about 40 percent. The composition is 58.5 wt % Organic Medium Composition 82 wt % of acetic ether 6 wt % of methyl ethyl ketone, 2 wt % of diethylene glycol diethyl ether, 0.5 wt % of dibutyl phthlate, 2 wt % of ethylcellulose, 7.5 wt % of VARCUM®, 37.5 wt. % silver powder (spherical silver, D50 0.1 to 3 μm), 1.0 wt. % Bi—Al—B based glass frit, 3.0 wt % Ethyl acetate. The mixture was jar milled for 12 to 15 hours, the beads screened and the composition was casted on a polyethylene terephthalate (PET) film using a doctor blade with an opening of 15 micrometers. The cast sheet was air dried for 15 minutes followed by oven drying at 80° C. for 10 minutes. The transfer sheet with silver thick film was ready for use.

### (B) Formation of Photohardenable Tacky Composition

A positive photohardenable tacky sheet for a photohardenable tacky layer was formed based on the following composition. 10 wt % of Acrylic Polymer as an organic binder and 75.7 wt % of propylene glycol methyl ether acetate as a solvent were mixed. Then, 2.1 wt % of a photopolymerizable monomer and 3.2 wt % of a photoinitiator were added to the organic mixture. 9.1 wt % of additives of plasticizer, inhibiter and thickner were added to the organic mixture. The materials were mixed well to be a photohardenable tacky composition. The mixture is jar milled for 12 to 15 hours, the beads screened and the composition was cast on a PET film. The cast sheet was air dried for 15 minutes followed by oven drying at 80° C. for 10 minutes, and then covered with a polyethylene (PE) film. The thickness of the photohardenable tacky layer was 20 um.

### (C) Formation of an Electrode

The PE film was stripped off the photohardenable tacky sheet, and then the photohardenable tacky layer was affixed to a glass substrate with 350 mm long, 300 mm wide and 2.8 mm thick. The photohardenable tacky sheet was exposed, from above the PET film, via a photomask having a line pattern 280 mm long. The line widths varied between 20 μm, 30 μm and 40 μm (Table 1). The PET film was stripped off after exposure. A transfer sheet was laminated onto the imaged film with the thick film side of the transfer sheet facing the imaged layer. For lamination there was used a roll press laminator (Va −700, Taisei Laminator Co., Ltd). FIG. 2 is a conceptual diagram of the present example in which the thick film composition of a transfer sheet 23 is pressure-bonded to a tacky layer 22 on a glass substrate 21, using a laminator. The pressure during running of the transfer sheet and the photohardenable layer between the rollers 24 of the laminator was set at 5 kg/cm. The transfer speed with which the transfer sheet and the photohardenable layer were run was set to 1.0 m/min. The thick film composition of the transfer sheet was pressure-bonded to the tacky layer 22 with the rollers 24 heated at 21° C., 35° C., 50° C., 80° C. and 120° C., as given in Table 1. After transfer of the transfer sheet onto the imaged photohardenable layer using the laminator, peeling the transfer sheet produced the desired pattern where the unexposed areas of the imaged layer remained tacky and the thick film was disposed on the tacky areas. The structure was fired at 500° C. in air using a standard thick film firing profile for displays.

### (D) Results

Line patterns after transferring the thick film were observed under the microscope. Instances in which breaks were observed in the pattern, or in which a desired pattern was not formed on account of excessive transfer of thick film composition, were rated as NG, while instances in which no breaks were observed were rated as OK. Regardless of line width, unbroken good line patterns were formed in Examples 1 to 9, where the rolls had been heated at 35° C., 50° C. and 80° C. during lamination. By contrast, breaks in the line pattern after firing were observed in Comparative examples 1, 3 and 5, where the rolls had been heated at 21° C. In Comparative examples 2, 4 and 6, where the rolls had been heated at 120° C., the thick film composition of the transfer sheet was transferred onto the entire surface of the tacky layer but failed to yield a line pattern after firing, and an excessive conductive film formed instead.

The above results indicated that a good thick film pattern is formed, even without application of high pressure, by carrying out lamination under heating. Conceivably, however, a good line pattern can also be formed by adjusting the temperature and transfer speed, even under conditions other than those of Examples 1 to 9. For instance, an excellent pattern is expected to be formed by setting the transfer speed to 0.5 m/min, even for a heating temperature of 20° C. Likewise, a good pattern is expected to be formed by setting the heating time to 2.0 m/min, even for a heating temperature of 120° C.

TABLE 1

| | Target line | | |
|---|---|---|---|
| | width | | |
| | (μm) | Temprature | |
| Comparative | 20 | 21 | NG |
| example 1 | | | |
| Example 1 | 20 | 35 | OK |
| Example 2 | 20 | 50 | OK |
| Example 3 | 20 | 80 | OK |
| Comparative | 20 | 120 | NG |
| example 2 | | | |
| Comparative | 30 | 21 | NG |
| example 3 | | | |
| Example 4 | 30 | 35 | OK |
| Example 5 | 30 | 50 | OK |
| Example 6 | 30 | 80 | OK |
| Comparative | 30 | 120 | NG |
| example 4 | | | |
| Comparative | 40 | 21 | NG |
| example 5 | | | |
| Example 7 | 40 | 35 | OK |
| Example 8 | 40 | 50 | OK |
| Example 9 | 40 | 80 | OK |
| Comparative | 40 | 120 | NG |
| example 6 | | | |

What is claimed is:

1. A process for forming a pattern having electrically functional properties on a substrate comprising the steps of:
(a) providing a photosensitive layer having a tacky surface disposed on a substrate;
(b) image-wise exposing the photosensitive layer to form an imaged layer having tacky and non-tacky areas;
(c) applying a sheet comprising at least one layer of a thick film composition, wherein said thick film composition comprises electrically functional powders, disposed on a support to the imaged layer wherein the imaged layer is in contact with the thick film composition of the sheet;
(d) heating the transfer sheet and the photohardenable layer to increase the adhesive strength between the thick film composition and tacky areas of the imaged layer;
(e) removing the support wherein the thick film composition remains on the support in the non-tacky areas of the imaged layer and the thick film composition substantially adheres to the tacky areas of the imaged layer forming a patterned article; and
(f) heating the thick film composition of the patterned article.

2. A process for forming a pattern having electrically functional properties on a substrate of claim 1 wherein the heating temperature in step (d) ranges from 30° C. to 100° C.

3. A process for forming a pattern having electrically functional properties on a substrate of claim 1, wherein in step (d), the transfer sheet and the photohardenable layer are pressure-bonded using a surface-heated roll.

4. A process for forming a pattern having electrically functional properties on a substrate of claim 3, wherein the transfer speed of the transfer sheet and the photohardenable layer in step (d) ranges from 0.5 m/min to 5.0 m/min.

5. A process for forming a pattern having electrically functional properties on a substrate comprising the steps of:
(a) providing a photosensitive layer having a tacky surface disposed on a substrate;
(b) applying a sheet comprising at least one layer of a thick film composition disposed on a support to the layer in (a) wherein layer (a) layer is in contact with the thick film composition of the sheet resulting in full coverage of the tacky surface by the thick film composition
(c) heating the transfer sheet and layer (a) to increase the adhesive strength between the thick film composition and tacky area of layer (a);
(d) removing the support wherein the thick film composition substantially adheres to the tacky areas; and
(e) heating the resulting thick film composition.

6. The process of claim 1 wherein the eletrically functional powder in the thick film composition is a conductor, a resistor or a dielectric.

7. The process of claim 7 wherein the electrically functional powder is a conductor and is selected from the group consisting of gold, silver, copper, nickel, aluminum, platinum, palladium, molybdenum, tungsten, tantalum, tin, indium, lanthanum, gadolinium, boron, ruthenium, cobalt, titanium, yttrium, europium, gallium, sulfur, zinc, silicon, magnesium, barium, cerium, strontium, lead, antimony, conductive carbon, and combinations thereof.
